(19) United States
(12) Patent Application Publication
(10) Pub. No.: US 2021/0358968 A1
(43) Pub. Date: Nov. 18, 2021

(54) ARRAY SUBSTRATE AND MANUFACTURING METHOD THEREOF

(71) Applicant: Wuhan China Star Optoelectronics Semiconductor Display Technology Co., Ltd., Wuhan (CN)

(72) Inventor: Pinquan XU, Wuhan (CN)

(73) Assignee: Wuhan China Star Optoelectronics Semiconductor Display Technology Co., Ltd., Wuhan (CN)

(21) Appl. No.: 16/631,198

(22) PCT Filed: Jan. 14, 2019
(86) PCT No.: PCT/CN2019/071579

§ 371 Date: Jan. 15, 2020

(30) Foreign Application Priority Data
Dec. 17, 2018 (CN) 201811544629.7

(51) Int. Cl. H01L 27/12

(52) U.S. Cl. CPC H01L 27/1222; H01L 27/1288; H01L 27/127; H01L 27/124

(57) ABSTRACT

An array substrate and manufacturing method thereof are provided. The method includes the following steps: fabricating an array substrate, in which a non-display portion at a side of a display portion of the array substrate is provided with a curved with region. The display portion includes an inorganic film layer and a thin film transistor, and the non-display portion includes a groove corresponding to the curved region and penetrating through the inorganic film layer. The method then includes fabricating a first planarization layer on the inorganic film layer, in which the first planarization layer fills into the groove and the first planarization layer is patterned to form via-holes in the planarization layer, and fabricating a metal layer on the first planarization layer so as to form an auxiliary electrode connecting with the thin film transistor.

### TECHNICAL FIELD

The present disclosure relates to the field of manufacturing method of a display, and, in particular, to an array substrate and a manufacturing method thereof.

### BACKGROUND ART

In the design of the organic light emitting diode (OLED) flexible array substrate, a groove is defined in the curved region of the substrate and an organic material is filled in the groove so as to increase the bending performance of the substrate. In addition, in the display region, a double-layered source-drain (SD) structure is used, in which one layer is used for Vdata lines in the display portion, and the other layer is used for Vdd lines to minimize voltage drops of the Vdd and improve product quality.

### Technical Problem

Generally, this type of array substrate requires 14 photomasks in the design, so that the process is quite complicated; in addition, the requirement for more photomasks increases the production cost, and the device is easily damaged in a multi-etching process.

Therefore, the prior art has drawbacks and is in urgent need for improvement.

### Technical Solution

The present disclosure provides an array substrate and a manufacturing method thereof, which may reduce the number of photomasks used for manufacturing the array substrate, thereby improving productivity and reducing cost.

To achieve the above objects, the present disclosure provides the following technical proposals.

The present disclosure provides a manufacturing method of an array substrate, the method including the following steps:

step S10: providing an array substrate, in which the array substrate includes a display portion including at least one thin film transistor located in an inorganic film layer, and a non-display portion provided with a curved region at a side of the display portion, wherein the non-display portion includes a groove corresponding to the curved region and penetrating through the inorganic film layer and first signal lines located at both sides of the groove;

step S20, fabricating a first planarization layer on the inorganic film layer, in which the first planarization layer is filled into the groove, and the first planarization layer is patterned to form a plurality of via-holes in the first planarization layer, the plurality of via-holes corresponding to the at least one thin film transistor and the first signal lines; and

step S30, fabricating a metal layer on the first planarization layer and patterning the metal layer to form an auxiliary electrode electrically connecting with the at least one thin film transistor through the plurality of via-holes in the first planarization layer and located in the display portion, and second signal lines located in the non-display portion and electrically connecting with the first signal lines through the plurality of via-holes in the first planarization layer.

In the manufacturing method of the present disclosure, before the step S10, the method further includes the following steps:

step S101: fabricating an active layer, a gate insulating layer, a gate electrode, and an interlayer insulating layer sequentially on the array substrate;

step S102; implementing a photomask process on the interlayer insulating layer and the gate insulating layer, so as to form source/drain via-holes connecting with the active layer in the display portion, and to form a first intermediate groove located in the curved region and penetrating through a portion of the inorganic film layer; and

step S103, fabricating a source/drain metal layer on the interlayer insulating layer, and patterning the source/drain metal layer to obtain a source/drain located in the display portion and electrically connecting with the active layer, and the first signal lines at both sides of the first intermediate groove of the non-display portion.

In the manufacturing method of the present disclosure, the method further includes the following steps:

step S104, fabricating a passivation layer on the source/drain and implementing a patterning process, so as to form via-holes in the passivation layer, which are corresponding to the sources/drains and the first signal lines, and to form a second intermediate groove at a position corresponding to the first intermediate groove, the second intermediate groove penetrating through the inorganic film layer and positioned over the first intermediate groove, wherein the second intermediate groove and the first intermediate groove are combined together to form the groove.

In the manufacturing method of the present disclosure, in the patterning process of the passivation layer, a third intermediate groove penetrating through the passivation layer and positioned over the first intermediate groove is also formed in the curved region, and the third intermediate groove, the second intermediate groove, and the first intermediate groove are combined together to form the groove.

In the manufacturing method of the present disclosure, the method further includes the following steps:

step S104: fabricating a passivation layer on the sources/drains and implementing a patterning process, so as to form via-holes in the passivation layer corresponding to the sources/drains and the first signal lines;

step S105: patterning the remaining inorganic film layer corresponding to the first intermediate groove, so as to form the second intermediate groove penetrating through the inorganic film layer and positioned over the first intermediate groove, wherein the second intermediate groove and the first intermediate groove are combined together to form the groove.

In the manufacturing method of the present disclosure, in the patterning process described in step S104, the third intermediate groove penetrating through the passivation layer and positioned over the first intermediate groove is also formed in the curved region. The third intermediate groove, the second intermediate groove, and the first intermediate groove are combined together to form the groove.

In the manufacturing method of the present disclosure, the method further includes the following steps:

step S40: fabricating a second planarization layer on the auxiliary electrodes and implementing a patterning process, so as to form a plurality of via-holes in the second planarization layer corresponding to the auxiliary electrodes;

step S50: fabricating patterned anodes on the second planarization layer, wherein the anodes are electrically connected to the auxiliary electrodes through the plurality of via-holes in the second planarization layer, and are electrically connected to the at least one thin film transistor through the auxiliary electrodes.

In order to achieve the above object, the present disclosure further provides an array substrate manufactured by the above manufacturing method. The array substrate includes a display portion including at least one thin film transistor located in the inorganic film layer, a non-display portion that is at a side of the display portion, provided with a curved region and including a groove corresponding to the curved region and penetrating through the inorganic film layer and first signal lines located at both sides of the groove, and a first planarization layer disposed on the inorganic film layer and filled into the groove, wherein the first planarization layer is made of an organic material.

In the array substrate of the present disclosure, the inorganic film layer includes a buffer layer, a gate insulating layer, an interlayer insulating layer, and a passivation layer that are sequentially stacked on a flexible substrate, and the source/drain via-holes penetrating through the insulating layer and the gate insulating layer are provided in the display portion of the inorganic film layer. The groove includes a first intermediate groove and a second intermediate groove stacked with and positioned over each other, wherein the first intermediate groove and the source/drain via-holes are formed by the same photomask.

In the array substrate of the present disclosure, the via-holes in passivation layer penetrating through the passivation layer are formed at the position corresponding to the source/drain of the at least one thin film transistor and the first signal lines, and the second intermediate groove and the via-holes in the passivation layer are formed by the same photomask.

In the array substrate of the present disclosure, the groove further includes a third intermediate groove penetrating through the passivation layer and positioned over the first intermediate groove, wherein the first intermediate groove is positioned over the second intermediate groove.

### Advantageous Effects

Advantageous effect of the present invention is to provide an array substrate and a manufacturing method thereof. Compared with the manufacturing method of the array substrate in the prior art, the method of the present disclosure is provided that the first intermediate groove of the curved region of the array substrate and the source/drain via-holes are formed by the same photomask process, and the second intermediate groove and via-holes in the passivation layer are formed by the same photomask process, and the planarization layer is filled into the groove, thereby greatly reducing the number of photomasks used, saving production cost, and avoiding damage to the device during multi-etching processes.

### BRIEF DESCRIPTION OF THE DRAWINGS

In order to more clearly illustrate the embodiments or the technical proposals in the prior art, the drawings to be used in the embodiments or the prior art description will be briefly described below. Obviously, the drawings in the following description are merely inventions. For some embodiments, other drawings may be obtained from those skilled in the prior art without any creative work.

FIG. 1 illustrates a flow chart of a method for fabricating an array substrate according to a first embodiment of the present disclosure;

FIGS. 2A-2B are schematic diagrams showing the method for fabricating an array substrate according to the first embodiment of the present disclosure;

FIG. 3 is a flow chart of a method for fabricating an array substrate according to a second embodiment of the present disclosure;

FIGS. 4A to 4C are schematic diagrams showing the method for fabricating the array substrate according to the second embodiment of the present disclosure; and

FIGS. 5A-5B are schematic diagrams showing a method for fabricating an array substrate according to a third embodiment of the present disclosure.

### DETAILED DESCRIPTION OF THE PREFERRED EMBODIMENTS

The following description of the various embodiments is provided to illustrate the specific embodiments of the invention. Directional terms as mentioned in the present disclosure, such as [upper], [lower], [front], [back], [left], [right], [inside], [outside], [side], etc., are merely for reference to the direction of the additional schema.

Therefore, the directional terminology used is for the purpose of illustration and understanding of the present invention. In the figures, structurally similar elements are denoted by the same reference numerals.

The present disclosure is to provide a method for fabricating an array substrate which possesses advantages over the prior art, in which the prior art has problems such as the photomask processing being used many times, the prior art method having a high production cost and the device manufactured thereby being easily damaged in a multi-etching processes. Such problems can be solved by the present invention.

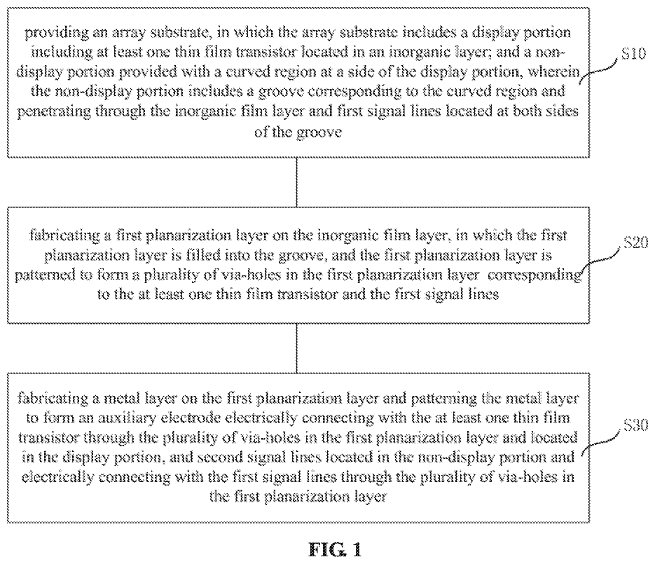

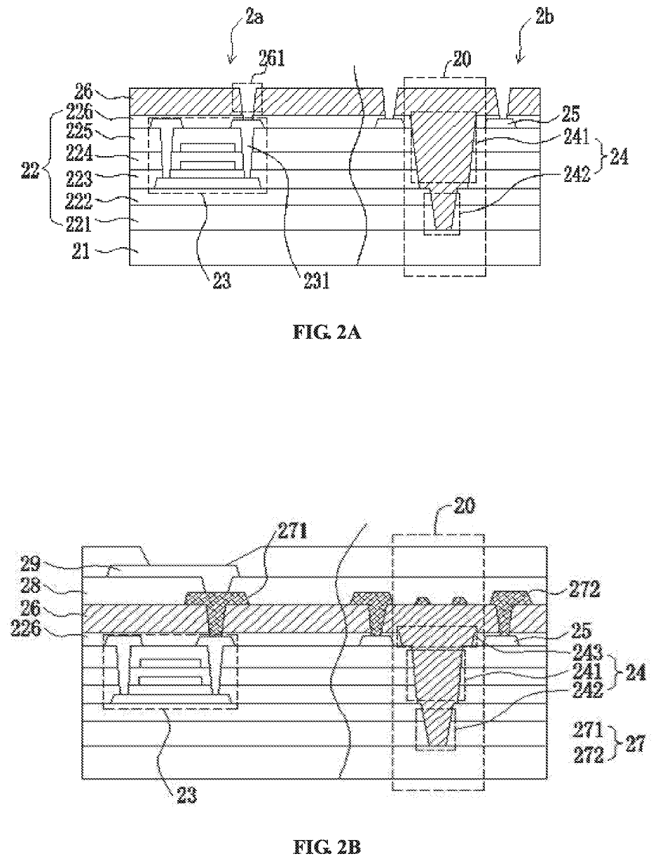

FIG. 1 is a flow chart of a method for fabricating an array substrate according to a first embodiment of the present disclosure. FIGS. 2A-2B are schematic diagrams showing the method for fabricating an array substrate according to the first embodiment of the present disclosure. The method includes the following steps:

step S10: providing an array substrate, in which the array substrate includes a display portion including at least one thin film transistor located in a inorganic film layer; and a non-display portion provided with a curved region at a side of the display portion, wherein the non-display portion includes a groove corresponding to the curved region and penetrating through the inorganic film layer and first signal lines located at both sides of the groove.

In reference to FIG. 2A, the array substrate includes a display portion 2a and a non-display portion 2b at a side of the display portion 2a, and the non-display portion 2b is provided with a curved region 20. The portion of the array substrate corresponding to the curved region 20 is configured for bending to achieve a display with a narrow bezel design. An inorganic film layer 22 is formed on the flexible substrate 21 of the array substrate, and at least one thin film transistor 23 is disposed in the inorganic film layer 22 corresponding to the display portion 2a. First signal lines 25 are disposed in the inorganic film layer 22 at both sides of the curved region 20 in the non-display portion 2b, wherein the first signal line 25 and the source/drain electrodes 231 in the at least one thin film transistor 23 are formed by the same photomask.

Thereafter, a first intermediate groove 241 and a second intermediate groove 242 are formed in the curved region 20 by performing a photomask process twice, and the first intermediate groove 241 and the second intermediate groove 242 are combined together to form a groove 24 penetrating through the inorganic film layer 22. That is, after completing the fabrication of the inorganic film layer 22, the groove 24 is formed in the curved region 20.

In the present embodiment, the inorganic film layer 22 includes, but is not limited to, a first buffer layer 221, a second buffer layer 222, a first gate insulating layer 223, a second gate insulating layer 224, an interlayer insulating layer 225, and a passivation layer 226.

A first planarization layer is fabricated on the inorganic film layer in step S20, so that the first planarization layer is filled into the groove. After patterning the first planarization layer, a plurality of via-holes in the first planarization layer corresponding to the at least one thin film transistor and the first signal lines are formed.

As shown in FIG. 2A, a first planarization layer 26 is fabricated on the inorganic film layer 22, so that the first planarization layer 26 is filled into the groove 24. After patterning the first planarization layer 26, the plurality of via-holes 261 in the first planarization layer which are corresponding to the source/drain electrodes 231 and the first signal lines 25 are formed.

The first planarization layer 26 is made of an organic material. The organic material filled in the groove 24 directly uses the material for forming the first planarization layer 26 which is formed at a subsequent process of the formation of the groove; therefore a photomask process to form the organic material filled in the groove 24 is omitted.

A metal layer is fabricated on the first planarization layer in step S30, and after patterning the metal layer, an auxiliary electrode connecting with the at least one thin film transistor through the plurality of via-holes in the first planarization layer is formed on the display portion, and second signal lines connecting with the first signal lines through the via-hole in the first planarization layer are formed in the non-display portion.

As shown in FIG. 2B, a metal layer 27 is formed on the first planarization layer 26, and the metal layer 27 is patterned by the same photomask so as to form an auxiliary electrode 271 electrically connecting with the source/drain electrodes 231 through the plurality of via-holes 261 in the first planarization layer and located in the display portion 2a, and to form second signal lines 272 electrically connecting with the first signal lines 25 through the plurality of via-holes 261 in the first planarization layer and located in the non-display portion 2b.

As shown in FIG. 2B, the method further includes the following steps:

step S40: fabricating a second planarization layer 28 on the auxiliary electrodes 271 and patterning the second planarization layer 28, so as to form a plurality of via-holes 281 in the second polarization layer which are corresponding to the auxiliary electrodes 271; and

step S50: fabricating anodes 29 on the second planarization layer 28 and patterning the anodes 29, so as to form patterned anodes electrically connecting with the auxiliary electrodes 271 through the plurality of via-hole 281 in the second planarization layer, and electrically connecting with the source/drain electrodes 231 through the auxiliary electrodes 271. Definitely, it is also possible to continue fabricating a pixel definition layer and a photo spacer, which is not limited herein.

Since the display portion 2a is in the form of the at least one thin film transistor 23 completed with the auxiliary electrodes 271, which form a double SD (source/drain) circuitry, wherein the source/drain electrodes 231 are served as data signal lines, and the auxiliary electrode 271 is served as a high voltage power supply (ie, a Vdd line). The non-display portion 2b employs the double-layered circuitry arrangement that the second signal lines 272 overlap on the first signal lines 25, so as to reduce the distance (pitch) between the lines. The second signal lines 272 are employed in the curved region 20, and the auxiliary electrode 271 is bridged with the first gate and the second gate of the thin film transistor 23 by employing the source/drain electrodes to reduce the interlay difference between the connected metal film layers to prevent the occurrence of etching abnormalities. The first planarization layer 26 within the groove 24 is remained during the photomask process in order to fill organic photoresist therein, thereby increasing the manufacture capability of the curved region 20.

In addition, during the etching process of the passivation layer 226, the passivation layer 226 of the curved region 20 is partially etched to form a third intermediate groove 243 penetrating through the passivation layer 226 and located over the first intermediate groove 241, wherein the first intermediate groove 241 is located over the second intermediate groove 242, thereby further increasing the bending ability of the array substrate.

The method for fabricating the array substrate provided in the second embodiment of the present invention is different from the first embodiment in that: in the second embodiment, the first intermediate groove of the groove is formed by the same photomask for forming the source/drain electrodes on the inorganic film layer, thereby further reducing the number in using the photomask.

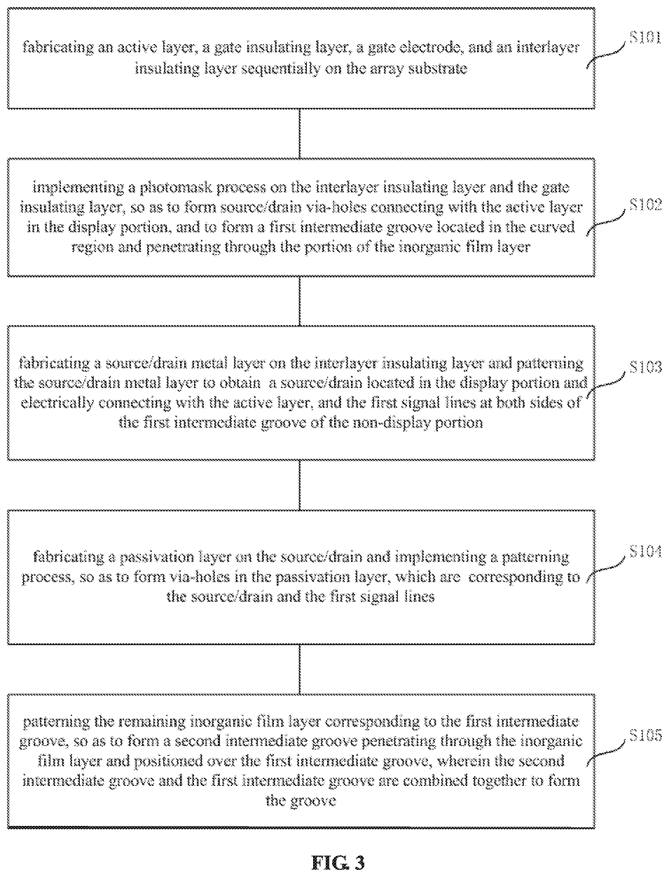

Specifically, as shown in FIG. 3, before the step S10 of the second embodiment, the method further includes the following steps:

step S101: fabricating an active layer, a gate insulating layer, a gate electrode, and an interlayer insulating layer sequentially on the array substrate.

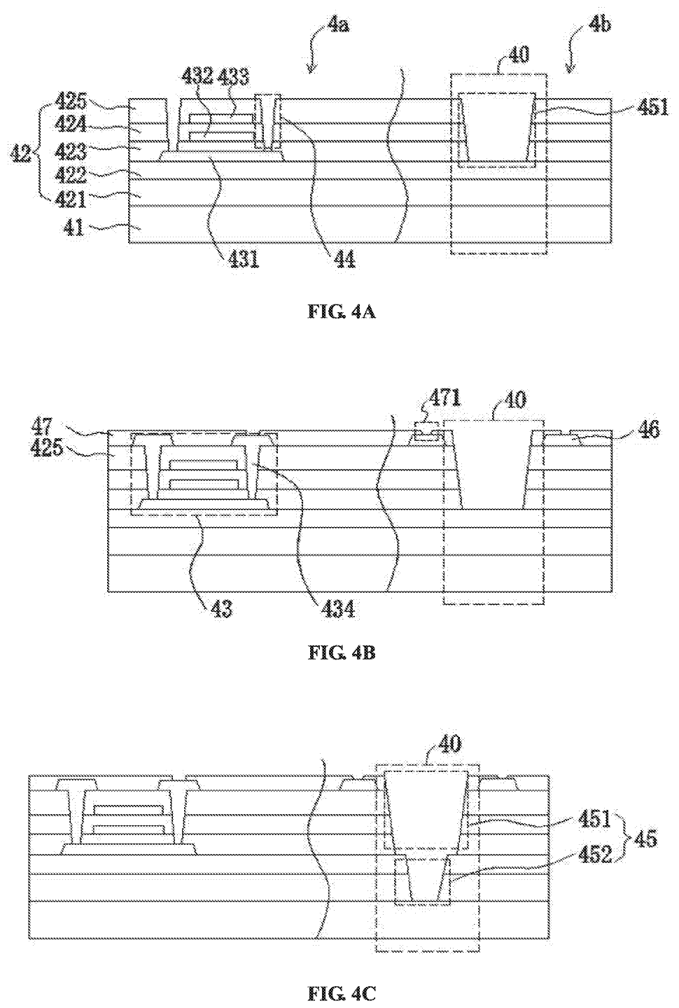

Referring to FIG. 4A, a first buffer layer 421, a second buffer layer 422, an active layer 431, a first gate insulating layer 423, a first gate electrode 432, and a second gate insulating layer 424, the second gate 433 and the interlayer insulating layer 425 are sequentially formed on the flexible substrate 41.

step S102: implementing a photomask process on the interlayer insulating layer and the gate insulating layer, so as to form the source/drain via-holes communicating with the active layer at the display portion, and to form a first intermediate groove penetrating through the portion of the inorganic film layer in the curved region.

As shown in FIG. 4A, after the completion of the photomask process, the source/drain via-holes 44 communicating with the active layer 431 are formed on the inorganic film layer 42 of the display portion 4a of the array substrate, and the first intermediate groove 451 penetrating through a portion of the inorganic film layer 42 is formed in the curved region 40 of the non-display portion 4b.

step S103: fabricating a source/drain metal layer on the interlayer insulating layer, and after patterning the source/drain metal layer, a source/drain electrically connecting to the active layer is formed at the display portion, and the first signal lines at both sides of the intermediate groove 451 are formed in the non-display portion.

As shown in FIG. 4B, a source/drain metal layer (not shown) is formed on the interlayer insulating layer 425, and after implementing the same photomask process, a source/drain 434 in the thin film transistor 43 is formed, and the first signal line 46 is formed at both sides of the intermediate groove 451.

step S104: fabricating a passivation layer on the source/drain and implementing the patterning process, so as to form via-holes in the passivation layer which are corresponding to the source/drain and the first signal lines.

As shown in FIG. 4B, a passivation layer 47 is formed on the source/drain electrodes 434 and is patterned to form via-holes 471 in the passivation layer which are corresponding to the source/drain electrodes 434 and the first signal lines 46.

step S105: patterning the remaining inorganic film layer corresponding to the first intermediate groove, so as to form a second intermediate groove penetrating through the inorganic film layer and positioned over the first intermediate groove, and the second intermediate groove and the first intermediate groove combine together to form the groove.

As shown in FIG. 4C, the remaining inorganic film layer 42 at the corresponding position of the first intermediate groove 451 is patterned to form a second intermediate groove 452 penetrating through the inorganic film layer 42 and positioned over the first intermediate groove 451. The second intermediate groove 452 and the first intermediate groove 451 combine together to form the groove 45.

Thereafter, the first planarization layer, the auxiliary electrode, the second signal lines, the second planarization layer, the anode, and the like are sequentially formed on the passivation layer 47, and details are not described herein. For details, please refer to the description in the first embodiment.

The method for fabricating the array substrate provided in the third embodiment of the present disclosure is different from the second embodiment in that: in the third embodiment, the second intermediate groove of the groove is formed by the same photomask for forming the via-holes in the passivation layer, thereby further reducing the number in using the photomask on the basis of the above-mentioned second embodiment.

The steps S101 to S103 in the foregoing second embodiment are the same as the fabrication method in the third embodiment. For details, please refer to the description in the second embodiment. After forming the array substrate described in the above-mentioned step S103, the embodiment is proceeded to the following steps:

step S104: fabricating a passivation layer on the source/drain and implementing a patterning process, so as to form the via-holes in the passivation layer which are corresponding to the source/drain and the first signal lines, and to form a second intermediate groove positioned corresponding to the first intermediate groove and penetrating through the inorganic film layer and positioned over the first intermediate groove. The second intermediate groove and the first intermediate groove combine together to form the groove.

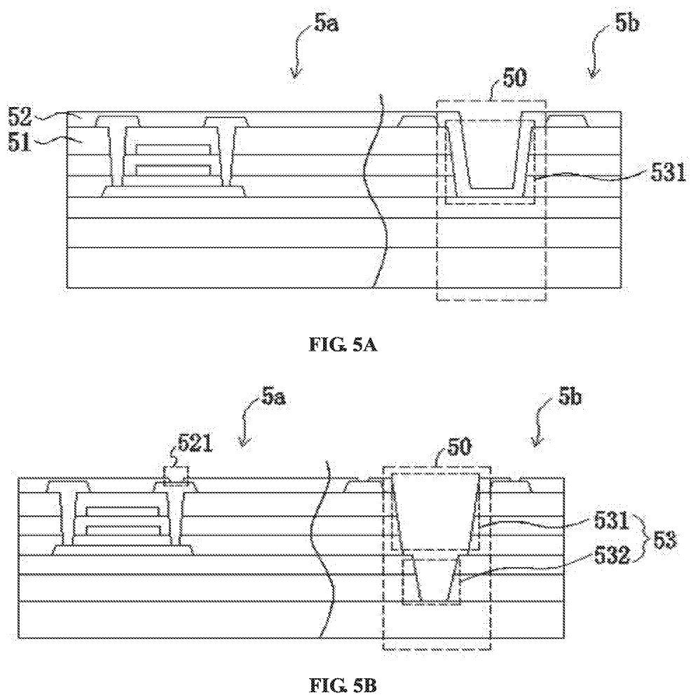

Referring to FIG. 5A, the array substrate includes a display portion 5a and a non-display portion 5b. A first intermediate groove 531 is formed in the curved region 50 of the non-display portion 5b, and the passivation layer 52 is formed on the interlayer insulating layer 51 of the array substrate.

Referring to FIG. 5B, a photomask process is implemented on the passivation layer 52, and a via-hole 521 in the passivation layer 52 is formed by implementing the same photomask process. The second intermediate groove 532 and the first intermediate groove 531 combine together to form the groove penetrating through the inorganic film layer in the curved region 50.

Definitely, in the implementation of patterning process described in step S104, a third intermediate groove (not shown in the figure) penetrating through the passivation layer 52 and positioned over the first intermediate groove 531 may be simultaneously formed in the curved region 50. The third intermediate groove, the second intermediate groove 532, and the first intermediate groove 531 combine together to form the groove 53.

Thereafter, the first planarization layer, the auxiliary electrode, the second signal lines, the second planarization layer, the anode, and the like are sequentially formed on the passivation layer 52, and details are not described herein. For details, please refer to the description in the first embodiment.

The present disclosure also provides an array substrate fabricated by the above manufacturing method. Please refer to the description in the above embodiments, and in conjunction with FIG. 2A-2B, or 4A-4C, or 5A-5B, the array substrate includes a display including a thin film transistor located in an inorganic film layer, a non-display portion provided with a curved region and located at a side of the display portion, wherein the non-display portion includes a groove penetrating through the inorganic film layer at the position corresponding curved region and first signal lines located at both sides of the groove. A first planarization layer is disposed on the inorganic film layer and filled into the groove, wherein the first planarization layer is made up of organic material, and the groove includes a first intermediate groove and a second intermediate groove that are superposed and positioned over each other.

In one embodiment, the first intermediate groove and the source/drain via-holes are formed by the same photomask.

In one embodiment, the second intermediate groove and the passivation layer via-holes are formed by the same photomask.

In one embodiment, the groove further includes a third intermediate groove positioned over the first intermediate groove, and the third intermediate groove, the second intermediate groove and the via-holes in the passivation layer are formed by the same photomask.

The present disclosure is related to providing an array substrate and a fabrication method thereof. The method of the present disclosure is provided that the first intermediate groove of the curved region of the array substrate and the source/drain via-holes are formed by implementing the same photomask process, and the second intermediate groove and via-holes in the passivation layer are formed by implementing the same photomask process, and the planarization layer is filled into the groove, thereby greatly reducing number in using the photomask, saving production cost, and avoiding damage to the device during multi-etching processes.

In the above, although the present disclosure has been disclosed in the above-mentioned preferred embodiments, the preferred embodiments are not intended to limit the present application, and those skilled in the art will appreciate that various modifications, additions and substitutions are possible, without departing from the scope and spirit of the invention, so the scope of protection of this application is subject to the scope defined by the claims.

1. A manufacturing method of an array substrate, wherein the method comprises the steps of:
step S10: providing an array substrate, in which the said array substrate includes a display portion including at least one thin film transistor located in an inorganic layer; and a non-display portion provided with a curved region at a side of the said display portion, where the said non-display portion includes a groove corresponding to the said curved region and penetrating through the said inorganic film layer and first signal lines located at both sides of the said groove;
step S20: fabricating a first planarization layer on the said inorganic film layer, in which the said first planarization layer is filled into the said groove, and the said first planarization layer is patterned to form a plurality of via-holes in the said first planarization layer, the said plurality of via-holes corresponding to the said at least one thin film transistor and the said first signal lines; and
step S30: fabricating a metal layer on the said first planarization layer and patterning the said metal layer to form an auxiliary electrode electrically connecting with the said at least one thin film transistor through the said plurality of via-holes in the said first planarization layer and located in the said display portion, and second signal lines located in the said non-display portion and electrically connecting with the said first signal lines through the said plurality of via-holes in the said first planarization layer.

2. The manufacturing method of claim 1, wherein before the step S10, the method further comprises the following steps:
step S101: fabricating an active layer, a gate insulating layer, a gate electrode, and an interlayer insulating layer sequentially on the said array substrate;
step S102: implementing a photomask process on the said interlayer insulating layer and the said gate insulating layer, so as to form source/drain via-holes connecting with the said active layer in the said display portion, and to form a first intermediated groove located in the said curved region and penetrating through a portion of the said inorganic film layer; and
step S103: fabricating a source/drain metal layer on the said interlayer insulating layer and patterning the said source/drain metal layer to obtain a source/drain located in the said display portion and electrically connecting with the said active layer, and the said first signal lines at both sides of the said first intermediate groove of the said non-display portion.

3. The manufacturing method of claim 2, wherein the method further comprises the steps of:
step S104: fabricating a passivation layer on the said source/drain and implementing a patterning process, so as to form via-holes in the said passivation layer, which are corresponding to the said sources/drains and the said first signal lines, and to form a second intermediate groove at a position corresponding to the said first intermediate groove, the said second intermediate groove penetrating through the said inorganic film layer and positioned over the said first intermediate groove, wherein the said second intermediate groove and the said first intermediate groove are combined together to form the said groove.

4. The manufacturing method of claim 3, wherein in the patterning process of the said passivation layer, a third intermediate groove penetrating through the said passivation layer and positioned over the said first intermediate groove is also formed in the said curved region, and the said third intermediate groove, the said second intermediate groove, and the said first intermediate groove are combined together to form the said groove.

5. The manufacturing method of claim 3, wherein the method further comprises the following steps:
step S104: fabricating a passivation layer on the said sources/drains and implementing a patterning process, so as to form via-holes in the said passivation layer corresponding to the said sources/drains and the said first signal lines; and
step S105: patterning the remaining said inorganic film layer corresponding to the said first intermediate groove, so as to form the said second intermediate groove penetrating through the said inorganic film layer and positioned over the said first intermediate groove, wherein the said second intermediate groove and the said first intermediate groove are combined together to form the said groove.

6. The manufacturing method of claim 5, wherein in the patterning process described in step S104, the said third intermediate groove penetrating through the said passivation layer and positioned over the said first intermediate groove is also formed in the said curved region; the said third intermediate groove, the said second intermediate groove, and the said first intermediate groove are combined together to form the said groove.

7. The manufacturing method of claim 1, wherein the method further comprises the following steps:
step S40: fabricating a second flat layer on the said auxiliary electrodes and implementing a patterning process, so as to form a plurality of via-holes in the said second planarization layer corresponding to the said auxiliary electrodes; and
step S50: fabricating patterned anodes on the said planarization layer, wherein the said anodes electrically are electrically connected to the said auxiliary electrodes through the said plurality of via-holes in the said second planarization layer, and are electrically connected to the said at least one thin film transistor through the said auxiliary electrodes.

8. The array substrate manufactured by the method of claim 1, wherein the array substrate comprises a display portion including at least one thin film transistor located in the said inorganic film layer; a non-display portion that is at a side of the said display portion, provided with a curved region and including a groove corresponding to the said curved region and penetrating through the said inorganic film layer and said first signal lines located at both sides of the said groove; and a first planarization layer disposed on the said inorganic film layer and filled into the said groove, wherein the said first planarization layer is made of an organic material.

9. The array substrate of claim 8, wherein the said inorganic film layer comprises a buffer layer, a gate insulating layer, an interlayer insulating layer, and a passivation layer that are sequentially stacked on a flexible substrate, and the said source/drain via-holes penetrating through the said insulating layer and the said gate insulating layer are provided in the said display portion of the said inorganic film layer, and the groove includes a first intermediate groove and a second intermediate groove stacked with and positioned over each other, wherein the said first intermediate groove and the said source/drain via-holes are formed by the same photomask.

10. The array substrate of claim 9, wherein the said via-holes in the said passivation layer penetrating through the said passivation layer are formed at the position corresponding to the said source/drain of the said at least one thin film transistor and the said first signal lines, and the said second intermediate groove and the said via-holes in the passivation layer are formed by the same photomask.

11. The array substrate of claim 9, wherein the said groove further includes a third intermediate groove penetrating through the said passivation layer and positioned over the said first intermediate groove, wherein the said first intermediate groove is positioned over the said second intermediate groove.
